(19) United States
(12) Patent Application Publication
(10) Pub. No.: US 2016/0360641 A1
(43) Pub. Date: Dec. 8, 2016

(54) ELECTRONIC DEVICE

(71) Applicant: FUJITSU LIMITED, Kawasaki-shi (JP)

(72) Inventors: Minoru FUJII, Kawasaki (JP); Hideaki MATSUMOTO, Yokohama (JP); Marco Scifoni, Kawasaki (JP); Kenji JOKO, Yokohama (JP); Katsumi Kanasaki, Machida (JP); Takaharu IZUNO, Kawasaki (JP); Mitsuaki HAYASHI, Kawasaki (JP); Osamu SAITO, Kawasaki (JP)

(73) Assignee: FUJITSU LIMITED, Kawasaki-shi (JP)

(21) Appl. No.: 15/160,317

(22) Filed: May 20, 2016

(30) Foreign Application Priority Data
Jun. 5, 2015 (JP) 2015-114636

(51) Int. Cl. H05K 7/20; H05K 1/02

(52) U.S. Cl. CPC H05K 7/20145; H05K 7/2039; H05K 1/0203

(57) ABSTRACT

An electronic device includes: a plurality of board units, each configured to include a board and a heat generation part installed on the board, the plurality of board units configured to be arranged in an axial direction perpendicular to the board; and a radiating structure configured to thermally connect with the heat generation part, and include a plurality of duct formation portions provided in the plurality of board units, the plurality of duct formation portions being arranged in the axial direction perpendicular to the board so that an air duct extending in an axial direction perpendicular to each board is formed.

### CROSS-REFERENCE TO RELATED APPLICATION

This application is based upon and claims the benefit of priority of the prior Japanese Patent Application No. 2015-114636, filed on Jun. 5, 2015, the entire contents of which are incorporated herein by reference.

### FIELD

The embodiments discussed herein are related to electronic devices.

### BACKGROUND

There is an existing electronic device provided with a plurality of board units, each having a board and a heat generation part installed on the board. In this electronic device, the plurality of board units are arranged in a direction perpendicular to the board. Moreover, in some of electronic devices of this kind, a cooling wind is supplied between the plurality of board units in parallel to each board unit.

Japanese Laid-open Patent Publications Nos. 2001-156483, 2007-227576, and 2014-53504 are examples of related art.

### SUMMARY

According to an aspect of the invention, an electronic device includes: a plurality of board units, each configured to include a board and a heat generation part installed on the board, the plurality of board units configured to be arranged in an axial direction perpendicular to the board; and a radiating structure configured to thermally connect with the heat generation part, and include a plurality of duct formation portions provided in the plurality of board units, the plurality of duct formation portions being arranged in the axial direction perpendicular to the board so that an air duct extending in an axial direction perpendicular to each board is formed.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view depicting the configuration of principal portions of an electronic device according to a first embodiment;

FIG. 2 is a side sectional view of the principal portions of the electronic device of FIG. 1;

FIG. 3 is a perspective view of a board unit of FIG. 1;

FIG. 4 is a perspective view of a board of FIG. 1;

FIG. 5 is a perspective view of a filler panel unit which is applied to the electronic device of FIG. 1;

FIG. 6 is a diagram depicting a modified example of the board unit of FIG. 1;

FIG. 7 is a perspective view depicting the configuration of principal portions of an electronic device according to a second embodiment;

FIG. 8 is a perspective view of the principal portions of the electronic device of FIG. 7, the principal portions viewed from a direction different from the direction of FIG. 7;

FIG. 9 is a perspective view of a board unit of FIG. 7;

FIG. 10 is a diagram depicting a modified example of the electronic device of FIG. 7;

FIG. 11 is a perspective view depicting the configuration of principal portions of an electronic device according to a third embodiment;

FIG. 12 is an exploded perspective view of a board unit of FIG. 11;

FIG. 13 is a perspective view of a board unit according to a fourth embodiment;

FIG. 14 is a perspective view of the board unit of FIG. 13, the board unit viewed from a direction different from the direction of FIG. 13;

FIG. 15 is a perspective view of the board unit of FIG. 13 from which a cooling member is removed;

FIG. 16 is a perspective view of the cooling member of FIG. 13;

FIG. 17 is a diagram depicting a modified example of the board unit of FIG. 13;

FIG. 18 is a side sectional view of a board unit according to a fifth embodiment; and

FIG. 19 is a perspective view depicting the configuration of principal portions of an electronic device according to a sixth embodiment.

### DESCRIPTION OF EMBODIMENTS

When a cooling wind is supplied between a plurality of board units in parallel to each board unit, a part (for example, a mechanism part or an optical module) installed in the board unit separately from a heat generation part sometimes becomes ventilation resistance. If a part different from the heat generation part becomes ventilation resistance as described above, the pressure loss of the cooling wind becomes large, which may cause a reduction in the efficiency of cooling of the heat generation part.

Moreover, when the cooling wind is supplied between the plurality of board units in parallel to each board unit, the capability of cooling the heat generation part may be increased by using a heat sink thermally connected to the heat generation part. However, in this case, there is a possibility that the cooling wind flows into a region other than a region in which the heat sink is disposed and the efficiency of cooling of the heat generation part is reduced.

### First Embodiment

First, a first embodiment of a technique that enhances the efficiency of cooling of the heat generation part will be described.

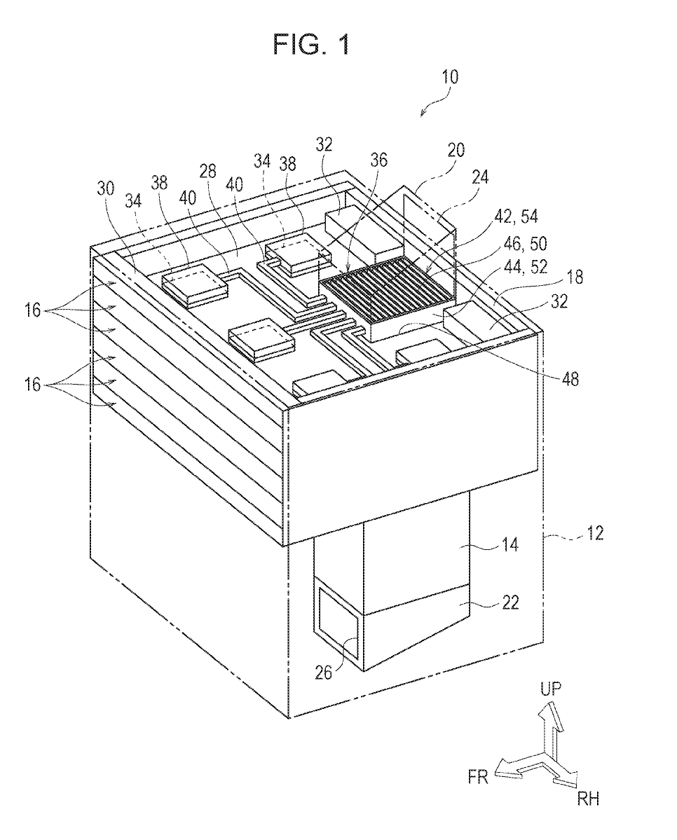

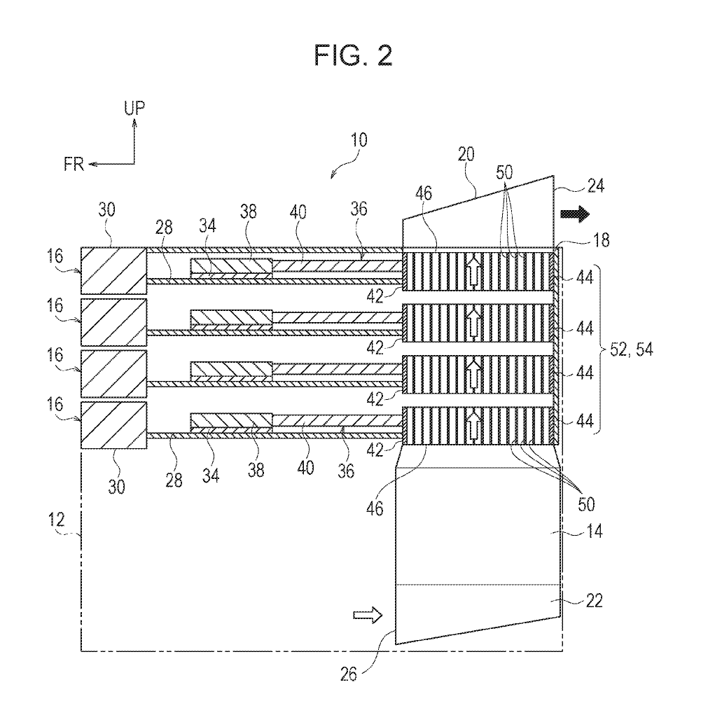

As depicted in FIGS. 1 and 2, an electronic device 10 according to the first embodiment includes a housing 12, a fan 14, a plurality of board units 16, and a back wiring board 18. Incidentally, an arrow FR, an arrow RH, and an arrow UP depicted in the drawings indicate a front side in a front-back direction, a right side in a width direction, and an upper side in a height direction, respectively, of the electronic device 10.

The housing 12 is formed in a box shape. In an upper part of the housing 12, an exhaust duct 20 is provided, and, in a lower part of the housing 12, an inlet duct 22 is provided. In the exhaust duct 20, an exhaust port 24 is formed, and, in the inlet duct 22, an inlet port 26 is formed. The fan 14 is connected to an upper side of the inlet duct 22.

The plurality of board units 16 each have a board 28 which is a printed circuit board. The plurality of board units 16 are arranged in a direction perpendicular to the board 28. That is, in the first embodiment, the boards 28 are disposed in such a way that a board-thickness direction of the board 28 corresponds to a height direction of the housing 12. Moreover, the plurality of board units 16 are transversely installed and arranged in the height direction of the housing 12 which is a direction perpendicular to the board 28.

This electronic device 10 has a bookshelf-type structure, and, in the housing 12, a plurality of slots arranged in the height direction of the housing 12 are formed. The plurality of board units 16, each being a plug-in unit (PIU), are housed in the housing 12 by being slid into the slots of the housing 12 from the front side thereof. In addition, the electronic device 10 is capable of implementing various functions by replacement of the plurality of board units 16.

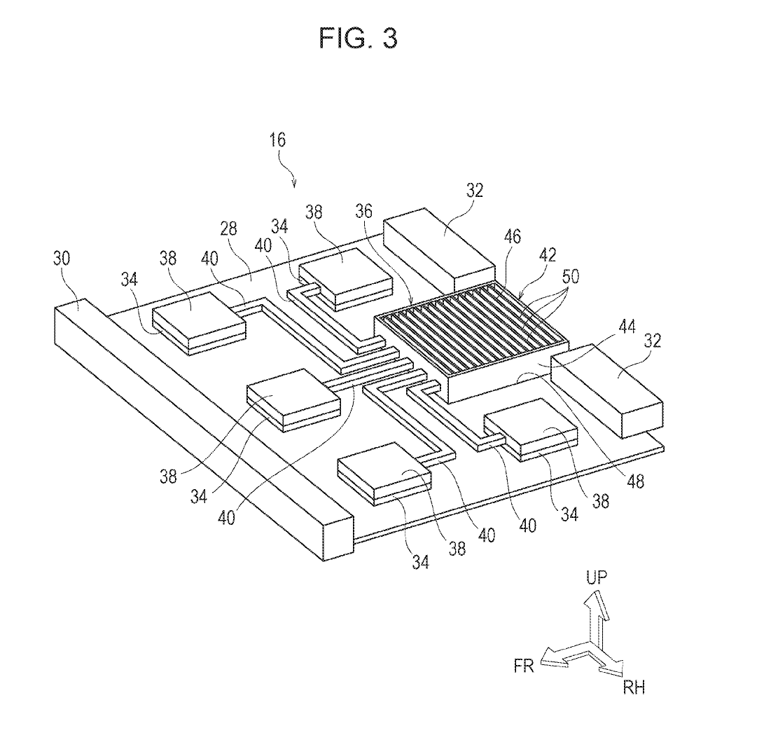

As depicted in FIG. 3, in addition to the above-described board 28, the plurality of board units 16 each have a front-face member 30, a connector 32, a plurality of heat generation parts 34, and a cooling member 36.

The board 28 is formed to have a substantially rectangular shape in a plan view. The front-face member 30 is provided along a front edge of the board 28, and the connector 32 is provided along a rear edge of the board 28. The connector 32 is connected to a connector of the back wiring board 18 (see FIGS. 1 and 2) provided behind the plurality of board units 16.

The heat generation parts 34 are installed on the board 28. Each heat generation part 34 is an electronic part which generates heat, such as a central processing unit (CPU).

The cooling member 36 has a plurality of heat receiving plates 38, a plurality of heat pipes 40, and a radiator 42. The plurality of heat receiving plates 38, the plurality of heat pipes 40, and the radiator 42 are formed of metal having high thermal conductivity, such as copper, and are integrated together by being joined together by welding or the like. Each heat receiving plate 38 is formed to have substantially the same shape and size as a corresponding heat generation part 34 in a plan view and placed on the heat generation part 34.

The heat pipes 40 connect the heat receiving plates 38 and the radiator 42. It is preferable to provide a height absorption function to joints between the heat receiving plates 38 and the heat pipes 40 and joints between the heat pipes 40 and the radiator 42. The heat receiving plates 38 and the heat pipes 40 are each an example of a “heat transfer member”.

Inside the heat pipes 40, a cooling medium is encapsulated. This cooling medium is evaporated by the heat of the heat receiving plates 38, and the evaporated cooling medium moves toward the radiator 42. Moreover, the cooling medium cooled in the radiator 42 is turned into liquid, and the cooling medium turned into liquid is moved toward the heat receiving plates 38 by capillary action of wicks provided in an inner wall of each heat pipe 40. Then, in the heat pipes 40, as a result of the movement of the cooling medium, the heat is transported to the radiator 42 from the heat receiving plates 38.

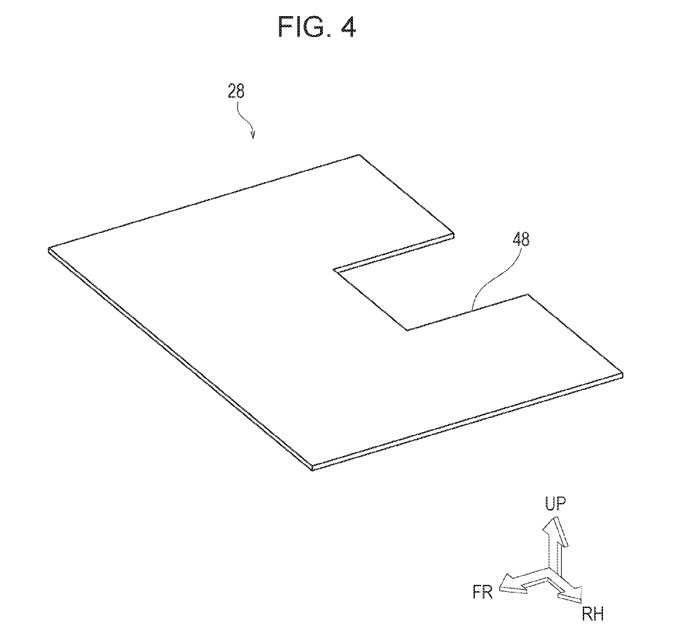

The radiator 42 has a duct formation portion 44 shaped like a rectangular frame and a radiating portion 46 provided inside the duct formation portion 44. On a rear edge side of the board 28, an opening 48 (see also FIG. 4) which is a rectangular notch in a plan view is formed, and the duct formation portion 44 is formed to have substantially the same shape and size as the opening 48 in a plan view. The duct formation portion 44 is passed through the board 28 in the board-thickness direction thereof and provided in the opening 48 in a state in which the duct formation portion 44 is housed in the opening 48. The duct formation portion 44 protrudes from both sides of the board 28 in the board-thickness direction of the board 28.

The radiating portion 46 has a plurality of radiating fins 50. The plurality of radiating fins 50 are formed in a direction in which the duct formation portion 44 passes through the board 28. The radiating portion 46 having the plurality of radiating fins 50 is formed integrally with the duct formation portion 44.

The plurality of heat generation parts 34 are sometimes disposed in positions which differ from specifications to specifications of the plurality of board units 16, but the radiator 42 is disposed in the same position in the plurality of board units 16. When the plurality of heat generation parts 34 are disposed in positions which differ from specifications to specifications of the plurality of board units 16, the shapes of the heat pipes 40 are changed depending on the positions of the plurality of heat generation parts 34.

As depicted in FIGS. 1 and 2, in a state in which the plurality of board units 16 are housed in the slots formed in the housing 12, an air duct 52 is formed as a result of the plurality of duct formation portions 44 provided in the plurality of board units 16 being arranged in a direction perpendicular to the board 28. This air duct 52 extends in a direction perpendicular to each board 28 and is disposed between the exhaust duct 20 and the fan 14. Moreover, a collective entity of the plurality of radiators 42 forming the air duct 52 forms a radiating structure 54.

In this electronic device 10, the plurality of heat generation parts 34 provided in the plurality of board units 16 are cooled in the following manner.

That is, when the fan 14 is activated, air is sucked in through the inlet duct 22. Moreover, the air sucked in through the inlet duct 22 and serving as the cooling wind flows to the exhaust duct 20 through the air duct 52 and is exhausted from the exhaust duct 20.

Furthermore, when the cooling wind flows through the air duct 52 in this manner, the plurality of radiating portions 46 provided inside the air duct 52 (the plurality of duct formation portions 44) are exposed to the cooling wind and cooled. The plurality of heat generation parts 34 installed on the boards 28 are thermally connected to the plurality of radiating portions 46 via the heat receiving plates 38, the heat pipes 40, and the duct formation portions 44. Therefore, when the plurality of radiating portions 46 are cooled, the plurality of heat generation parts 34 of the boards 28 are cooled.

Next, the operation and effect of the first embodiment will be described.

As described above in detail, according to the first embodiment, the duct formation portion 44 is provided in each of the plurality of board units 16, and the air duct 52 is formed as a result of the plurality of duct formation portions 44 being arranged in a direction perpendicular to the board 28. Therefore, since it is possible to collect the cooling wind from the fan 14 in the air duct 52, it is possible to reduce the pressure loss of the cooling wind.

Moreover, the air duct 52 is formed as the radiating structure 54 which is a collective entity of the plurality of radiators 42, and this radiating structure 54 is thermally connected to the heat generation parts 34. Therefore, it is possible to cool the heat generation parts 34 by the cooling wind collected in the air duct 52. As a result, it is possible to enhance the efficiency of cooling of the heat generation parts 34.

Furthermore, inside the air duct 52, the radiating portions 46 thermally connected to the heat generation parts 34 are provided. Therefore, as a result of the radiating portions 46 being provided, it is possible to increase the radiation area and thereby further enhance the efficiency of cooling of the heat generation parts 34 thermally connected to the radiating portions 46.

In addition, as a result of the air duct 52 extending in a direction perpendicular to the board 28, the exhaust duct 20 and the inlet duct 22 are placed in the upper and lower parts, respectively, of the housing 12. Therefore, as compared to a case where the inlet port and the exhaust port are provided in, for example, a front part and a rear part of the housing 12, it is possible to simplify the structure of the housing 12 in the front part and the rear part thereof, which makes it possible to make the electronic device 10 smaller in a front-back direction.

Moreover, the radiating portion 46 is provided inside each of the plurality of duct formation portions 44, and, in each of the plurality of board units 16, the radiating portion 46 is thermally connected to the heat generation parts 34. Therefore, since it is possible to radiate heat of the heat generation parts 34 by the radiating portion 46 in each of the plurality of board units 16, it is possible to further enhance the efficiency of cooling of the heat generation parts 34.

Furthermore, since the radiating portion 46 is provided in each of the plurality of board units 16 which are inserted into and removed from the housing 12, it is possible to simplify the structure of thermal connection between the heat generation parts 34 and the radiating portion 46.

In addition, in each board 28, the opening 48 which is a notch is formed, and the duct formation portion 44 forming the air duct 52 is provided in the opening 48. Therefore, since the air duct 52 is incorporated into the plurality of board units 16, it is possible to make the electronic device 10 smaller as compared to a case where the air duct 52 is placed outside the plurality of board units 16.

Moreover, in each board unit 16, the duct formation portion 44 and the radiating portion 46 are formed integrally. This makes it possible to suppress an increase in the number of parts and the number of assembly processes and thereby achieve cost reduction.

Furthermore, the plurality of radiating fins 50 provided in each radiating portion 46 are formed in a direction in which the duct formation portion 44 passes through the board 28. Therefore, it is possible to improve the radiation performance in the radiating portion 46 while suppressing ventilation resistance in the air duct 52.

In addition, since the heat pipes 40 are used to connect the heat generation parts 34 and the radiating portion 46, it is possible to enhance the efficiency of heat transfer from the heat generation parts 34 to the radiating portion 46.

Next, a modified example of the first embodiment will be described.

In the above-described first embodiment, the plurality of board units 16 are transversely installed, but the plurality of board units 16 may be longitudinally installed. That is, the boards 28 may be disposed in such a way that the board-thickness direction of the board 28 corresponds to a width direction of the housing 12, and the plurality of board units 16 may be arranged in the width direction of the housing 12 which is a direction perpendicular to the board 28.

Moreover, the above description deals with the plurality of board units 16 formed as plug-in units which are inserted into and removed from the slots formed in the housing 12, but the plurality of board units 16 may be provided by being fixed inside the housing 12.

Furthermore, the radiating portion 46 is provided in each of the plurality of board units 16. However, a common radiating portion shared by the plurality of board units 16 may be provided, and this common radiating portion may be thermally connected to the heat generation parts 34 of the board units 16.

In addition, the opening 48, which is formed as a notch, may be formed as a hole.

Moreover, the duct formation portion 44 and the radiating portion 46 are preferably formed integrally, but the duct formation portion 44 and the radiating portion 46 may be formed as separate component elements.

Furthermore, the radiating portion 46 has the plurality of radiating fins 50, but the radiating portion 46 may have a radiation structure other than the plurality of radiating fins.

In addition, each radiator 42 may be formed as a radiator which causes the cooling medium to circulate between the radiator and the heat pipes 40.

Moreover, the heat generation parts 34 and the radiating portion 46 are preferably connected via the heat pipes 40, but the heat generation parts 34 and the radiating portion 46 may be connected via a heat transfer member other than the heat pipe.

Furthermore, the above description deals with the fan 14 formed as a push-type fan and provided in the lower part of the housing 12, but the fan 14 may be formed as a pull-type fan and provided in the upper part of the housing 12.

In addition, the duct formation portion 44 is formed to have a shape like a rectangular frame, but the duct formation portion 44 may have any shapes other than a rectangular frame-like shape as long as the shapes allow formation of the air duct 52.

Moreover, in the above-described first embodiment, the air duct 52 is formed of the plurality of duct formation portions 44 provided in the plurality of board units 16. However, the air duct 52 may be formed of the plurality of duct formation portions 44 provided in the plurality of board units 16 and other members.

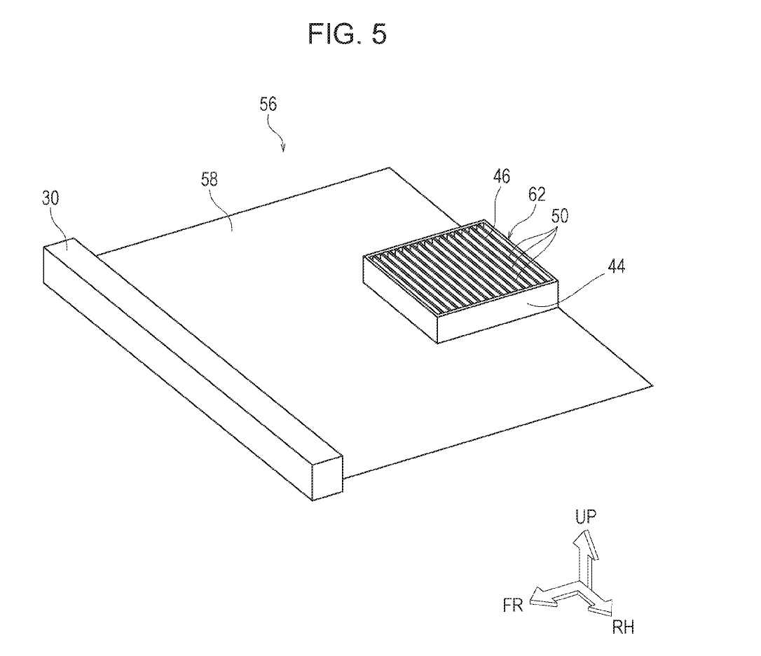

Furthermore, in the above-described first embodiment, in place of any one of the plurality of board units 16, a filler panel unit 56 depicted in FIG. 5 may be used. This filler panel unit 56 has a board 58 (a filler panel) and a radiator 62 which are similar to the board 28 and the radiator 42 in the board unit 16 described above.

When the filler panel unit 56 depicted in FIG. 5 is placed in the above-described electronic device 10, the duct formation portion 44 of each board unit 16 is an example of a “first duct formation portion” and the duct formation portion 44 of the filler panel unit 56 is an example of a “second duct formation portion”. The duct formation portions 44 of the board units 16 and the duct formation portion 44 of the filler panel unit 56 are capable of forming the above-described air duct 52 (see FIG. 2).

According to the modified example depicted in FIG. 5, when any one of the plurality of board units 16 is not used and removed, by using the filler panel unit 56 in place of this board unit 16, it is possible to suppress a break in the air duct 52. This makes it possible to suppress a reduction in the efficiency of cooling of the heat generation parts 34.

Incidentally, in the modified example depicted in FIG. 5, the radiating portion 46 may be omitted from the filler panel unit 56. That is, the filler panel unit 56 may have no radiating portion 46 and have a duct formation member formed of the duct formation portion 44. Such a configuration makes it possible to simplify the structure of the filler panel unit 56 and thereby achieve cost reduction.

Moreover, in the above-described first embodiment, the plurality of duct formation portions 44 forming the air duct 52 are preferably disposed with a space left therebetween in order to perform insertion and removal of the plurality of board units 16 smoothly. However, the plurality of duct formation portions 44 may be in contact with one another.

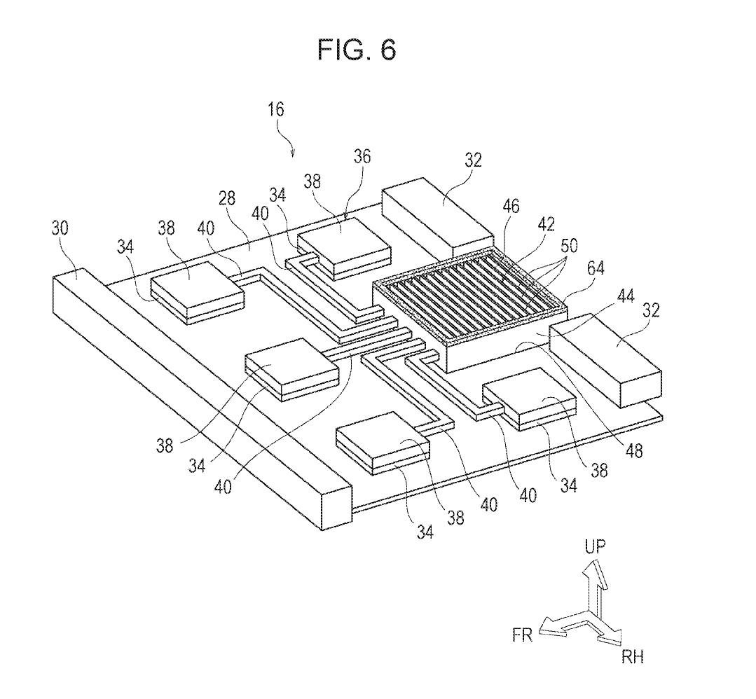

Furthermore, when the plurality of duct formation portions 44 are disposed with a space left therebetween, as depicted in FIG. 6, for example, a gasket 64 may be provided on a top face of each duct formation portion 44. Then, the space formed between the plurality of duct formation portions 44 may be filled with the gasket 64.

Since such a configuration makes it possible to fill the space formed between the plurality of duct formation portions 44 with the gasket 64, it is possible to suppress leakage of the cooling wind from the air duct 52. As a result, it is possible to further reduce the pressure loss of the cooling wind flowing through the air duct 52.

### Second Embodiment

Next, a second embodiment of the technique of the present disclosure will be described.

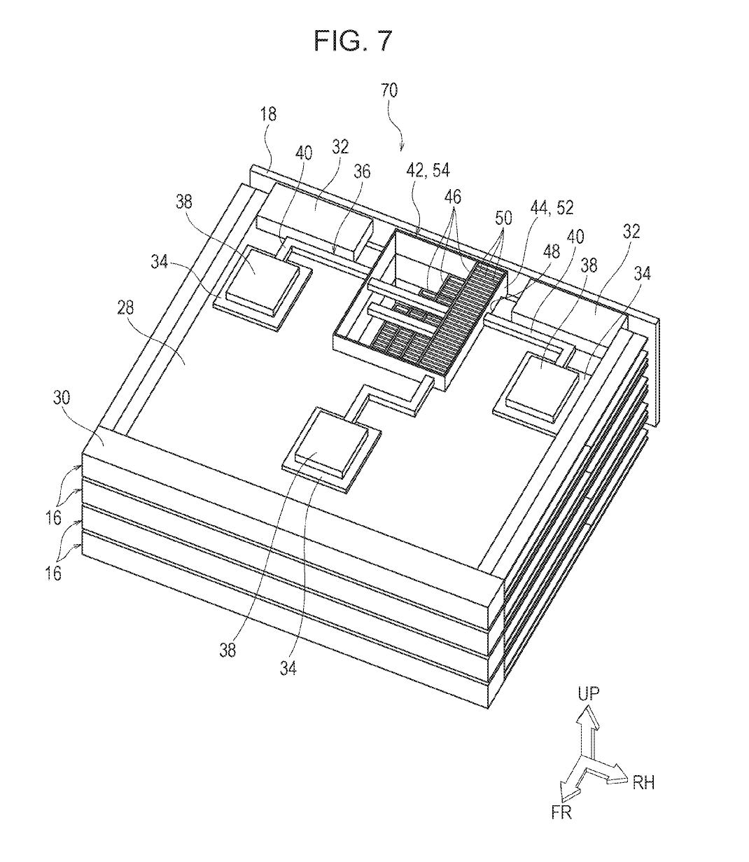

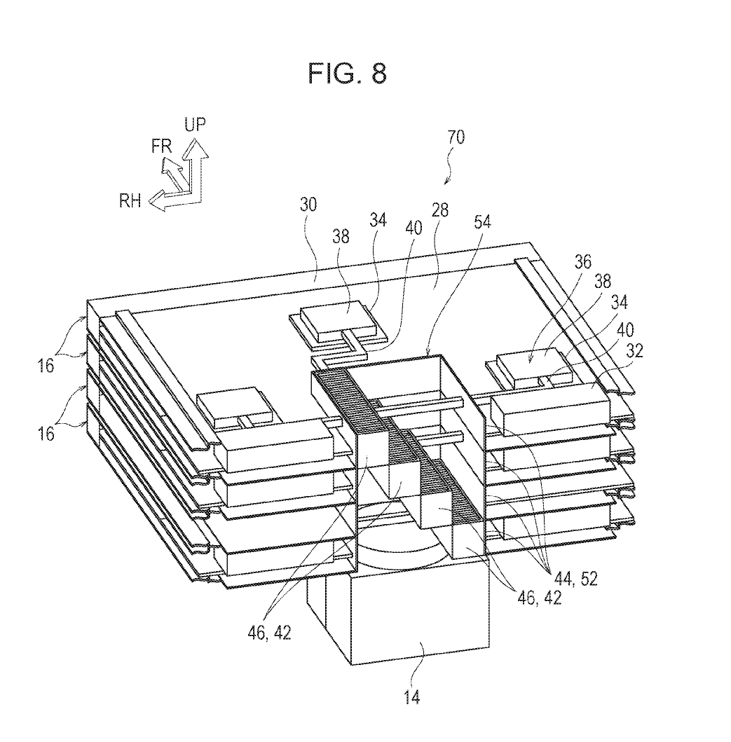

An electronic device 70 according to the second embodiment depicted in FIGS. 7 and 8 has a structure obtained by changing the structure of the electronic device 10 according to the above-described first embodiment as follows.

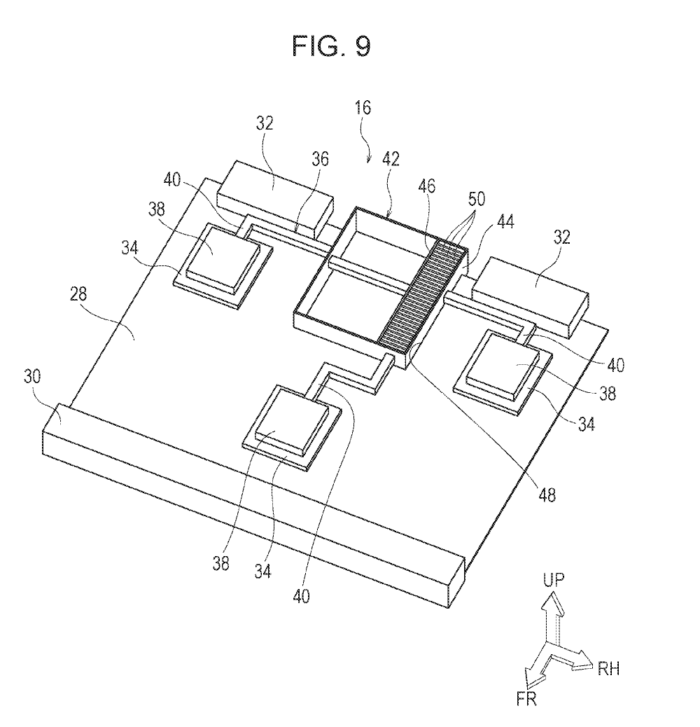

That is, in the electronic device 70 according to the second embodiment, the radiating portion 46 of the radiator 42 provided in each board unit 16 is formed to have a narrower width than the duct formation portion 44 (see also FIG. 9). In addition, the plurality of radiating portions 46 provided in the plurality of board units 16 are disposed in a staircase pattern as a result of the radiating portions 46 being sequentially displaced from one side to the other side in a width direction of the board 28.

In this electronic device 70, the placement position of the radiating portion 46 in each board unit 16 is previously set such that the plurality of radiating portions 46 form a staircase pattern in a state in which the plurality of board units 16 are placed in the electronic device 70. The placement position of the radiating portion 46 in each board unit 16 is set in accordance with the position of the slot in which each board unit 16 is to be placed.

Moreover, in the second embodiment, as a result of the plurality of radiating portions 46 being disposed in a staircase pattern, the radiating portions 46 of the radiators 42 adjacent to each other in an axial direction of the air duct 52 are disposed so as to be displaced in the width direction of the board 28. These radiating portions 46 of the adjacent radiators 42 are preferably disposed so as to be close to each other such that no space is left in the width direction of the board 28. The width direction of the board 28 is an example of a “direction orthogonal to the axial direction of the air duct”.

According to the second embodiment, the radiating portions 46 of the adjacent radiators 42 are disposed so as to be displaced in the width direction of the board 28. Therefore, it is possible to suppress transfer of the heat of the radiating portion 46 on the lower side (upstream side) to the radiating portion 46 on the upper side (downstream side) along with the flow of the cooling wind. This makes it possible to ensure the capability of cooling the heat generation parts 34 of the board unit 16 disposed on the upper side.

Moreover, the plurality of radiating portions 46 are disposed in a staircase pattern. Therefore, since the radiating portion 46 on the lower side is not disposed below the radiating portion 46 on the upper side, it is possible to ensure more effectively the capability of cooling the heat generation parts 34 of the board unit 16 disposed on the upper side. This makes it possible to cool uniformly the heat generation parts 34 of the board unit 16 disposed on the upper side and the heat generation parts 34 of the board unit 16 disposed on the lower side.

In the second embodiment, a configuration other than those described above is similar to the configuration of the above-described first embodiment. In the second embodiment, the configuration similar to the configuration of the above-described first embodiment produces the operation and effect similar to those of the above-described first embodiment.

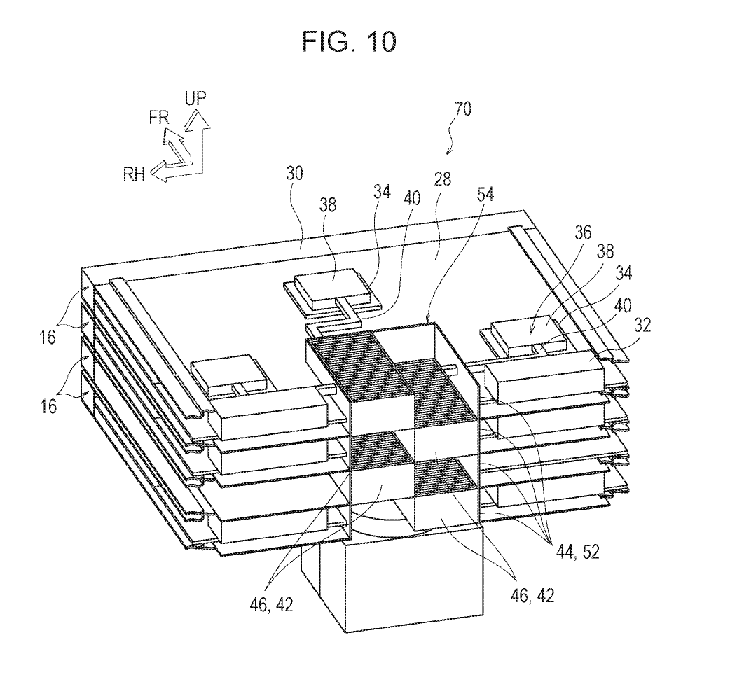

Incidentally, in the above-described second embodiment, as long as the radiating portions 46 of the adjacent radiators 42 are disposed so as to be displaced in a direction orthogonal to the axial direction of the air duct 52, the plurality of radiating portions 46 may be disposed alternately as depicted in FIG. 10, for example.

Such a configuration also makes it possible to suppress transfer of the heat of the radiating portion 46 on the lower side to the radiating portion 46 on the upper side along with the flow of the cooling wind. As a result, it is possible to ensure the capability of cooling the heat generation parts 34 of the board unit 16 disposed on the upper side.

Moreover, in the above-described second embodiment, the radiating portions 46 of the radiators 42 adjacent to each other in the axial direction of the air duct 52 are disposed so as to be displaced in the width direction of the board 28. However, the radiating portions 46 of the radiators 42 adjacent to each other in the axial direction of the air duct 52 may be disposed so as to be displaced in a front-back direction of the board 28. The front-back direction of the board 28 in this case is an example of the “direction orthogonal to the axial direction of the air duct”.

Furthermore, in the second embodiment, as for the configuration similar to the configuration of the above-described first embodiment, a modified example similar to that of the above-described first embodiment may be adopted.

### Third Embodiment

Next, a third embodiment of the technique of the present disclosure will be described.

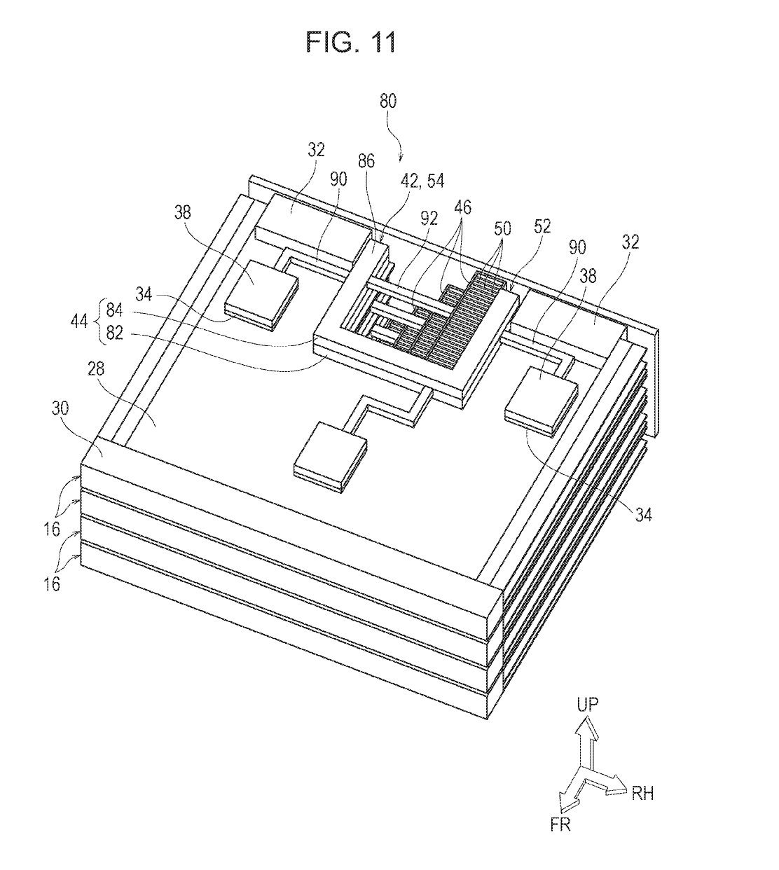

An electronic device 80 according to the third embodiment depicted in FIG. 11 has a structure obtained by changing the structure of the electronic device 70 according to the above-described second embodiment as follows.

That is, in the electronic device 80 according to the third embodiment, the duct formation portion 44 has a fixed portion 82 and a mounted portion 84. The fixed portion 82 and the mounted portion 84 are parts obtained by dividing the duct formation portion 44 into two parts in an axial direction (height direction) of the duct formation portion 44. The fixed portion 82 is fixed to the board 28, and the mounted portion 84 is mounted on the fixed portion 82. The mounted portion 84 is made fast to the fixed portion 82 by being secured thereto by a screw, for example.

The duct formation portion 44 formed of the fixed portion 82 and the mounted portion 84 is formed in the shape of a letter U lying on the side thereof (a letter C) with an opening on the side where the back wiring board 18 is located in a plan view. The opening in the air duct 52 formed of the plurality of duct formation portions 44, the opening on the side where the back wiring board 18 is located, is covered with the back wiring board 18.

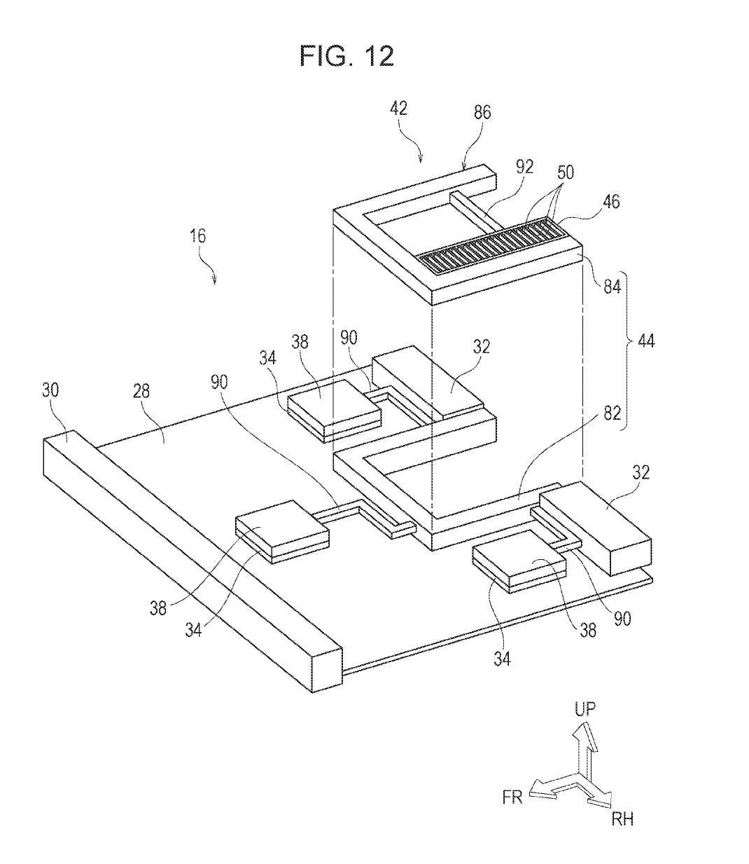

As depicted in FIG. 12, the radiating portion 46 is formed integrally with the mounted portion 84, and the mounted portion 84 and the radiating portion 46 form a cooling member 86. The cooling member 86 is formed of high radiation performance metal such as aluminum.

Moreover, in the electronic device 80 according to the third embodiment, a plurality of types of cooling members 86 are used in accordance with the positions in which the plurality of board units 16 are placed. In the plurality of types of cooling members 86, the position in which the radiating portion 46 is formed with respect to the mounted portion 84 in the width direction of the board 28 in one type of cooling member 86 is different from the position in which the radiating portion 46 is formed with respect to the mounted portion 84 in the width direction of the board 28 in the other type of cooling member 86.

In addition, as a result of the plurality of types of cooling members 86 being used as described above, the plurality of radiating portions 46 provided in the plurality of board units 16 are disposed in a staircase pattern by being sequentially displaced from one side to the other side in the width direction of the board 28. In this electronic device 80, the type of the cooling member 86 which is used in each board unit 16 is determined in accordance with the position in which the board unit 16 is placed, such that the plurality of radiating portions 46 form a staircase pattern.

Moreover, each board unit 16 has first heat pipes 90, each being an example of a “first heat transfer member”, and a second heat pipe 92 which is an example of a “second heat transfer member”. The heat generation parts 34 and the fixed portion 82 are connected via the heat receiving plates 38 and the first heat pipes 90, and the mounted portion 84 and the radiating portion 46 are connected via the second heat pipe 92. The first heat pipes 90 and the second heat pipe 92 are thermally connected via the fixed portion 82 and the mounted portion 84. Furthermore, the second heat pipe 92 is provided inside the duct formation portion 44.

According to the third embodiment, the plurality of types of cooling members 86 in which the position in which the radiating portion 46 is formed with respect to the mounted portion 84 in one type of cooling member 86 is different from the position in which the radiating portion 46 is formed with respect to the mounted portion 84 in the other type of cooling member 86 are used. Therefore, the plurality of types of cooling members 86 only have to be prepared to dispose the radiating portions 46 of the radiators 42 adjacent to each other in the axial direction of the air duct 52 such that the radiating portions 46 are displaced, and, as for the fixed portions 82, it is possible to use the fixed portions 82 having the same shape in the plurality of board units 16. As a result, the size of a member whose shape is changed is smaller than the size in a case where, for example, the overall shape of the radiator 42 is changed and a plurality of types of radiators 42 are prepared, which makes it possible to achieve cost reduction.

Moreover, the heat generation parts 34 and the fixed portion 82 are connected via the heat receiving plates 38 and the first heat pipes 90, and the mounted portion 84 and the radiating portion 46 are connected via the second heat pipe 92. Furthermore, the first heat pipes 90 and the second heat pipe 92 are thermally connected via the fixed portion 82 and the mounted portion 84. Therefore, even when the duct formation portion 44 is divided into the fixed portion 82 and the mounted portion 84, it is possible to thermally connect the heat generation parts 34 and the radiating portion 46 via the first heat pipes 90 and the second heat pipe 92. This makes it possible to ensure the capability of cooling the heat generation parts 34.

In addition, the second heat pipe 92 is provided inside the duct formation portion 44. Therefore, since it is possible to cool the second heat pipe 92 by the cooling wind, it is possible to enhance the capability of cooling the heat generation parts 34.

In the third embodiment, a configuration other than those described above is similar to the configurations of the above-described first and second embodiments. In the third embodiment, the configuration similar to the configurations of the above-described first and second embodiments produces the operation and effect similar to those of the above-described first and second embodiments.

Incidentally, in the above-described third embodiment, the heat generation parts 34 and the fixed portion 82 are connected via the heat receiving plates 38 and the first heat pipes 90, and the mounted portion 84 and the radiating portion 46 are connected via the second heat pipe 92. However, the first heat transfer member other than the heat pipe may be used to connect the heat generation parts 34 and the fixed portion 82, and, likewise, the second heat transfer member other than the heat pipe may be used to connect the mounted portion 84 and the radiating portion 46.

Since such a configuration also makes it possible to thermally connect the heat generation parts 34 and the radiating portion 46, it is possible to ensure the capability of cooling the heat generation parts 34.

Moreover, in the above-described third embodiment, in the plurality of types of cooling members 86, the position in which the radiating portion 46 is formed with respect to the mounted portion 84 in the width direction of the board 28 in one type of cooling member 86 is different from the position in which the radiating portion 46 is formed with respect to the mounted portion 84 in the width direction of the board 28 in the other type of cooling member 86, but the position in which the radiating portion 46 is formed with respect to the mounted portion 84 in the front-back direction of the board 28 in one type of cooling member 86 may be different from the position in which the radiating portion 46 is formed with respect to the mounted portion 84 in the front-back direction of the board 28 in the other type of cooling member 86. The front-back direction of the board 28 in this case is an example of the “direction orthogonal to the axial direction of the air duct”.

Furthermore, in the third embodiment, as for the configuration similar to the configurations of the above-described first and second embodiments, a modified example similar to those of the above-described first and second embodiment may be adopted.

### Fourth Embodiment

Next, a fourth embodiment of the technique of the present disclosure will be described.

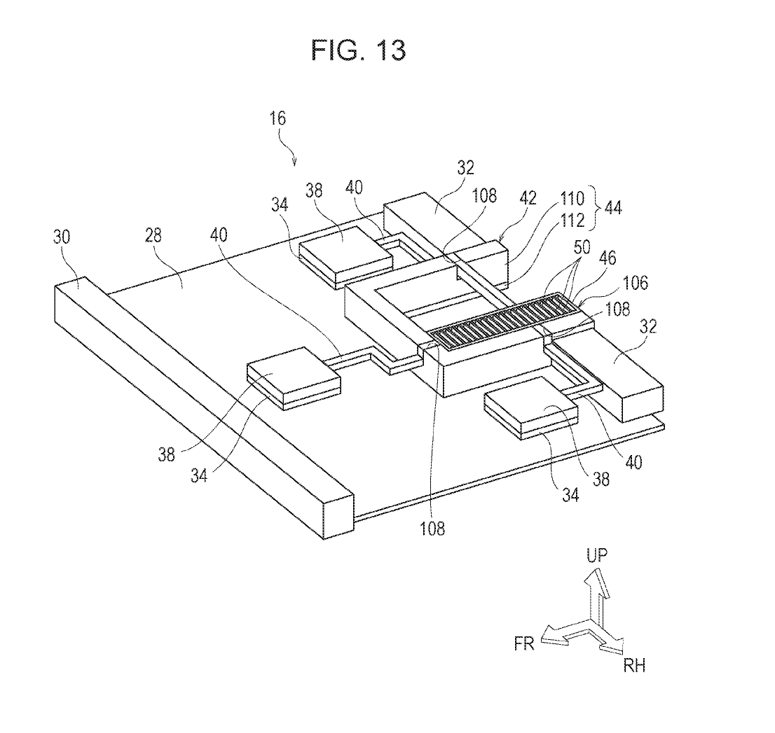

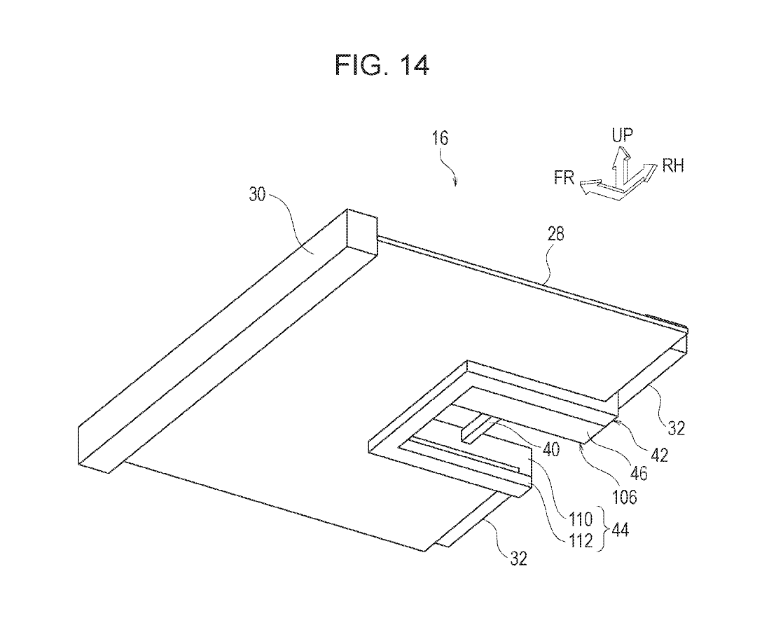

In the fourth embodiment depicted in FIGS. 13 to 16, the structure of the board unit 16 is changed from that of the above-described second embodiment as follows.

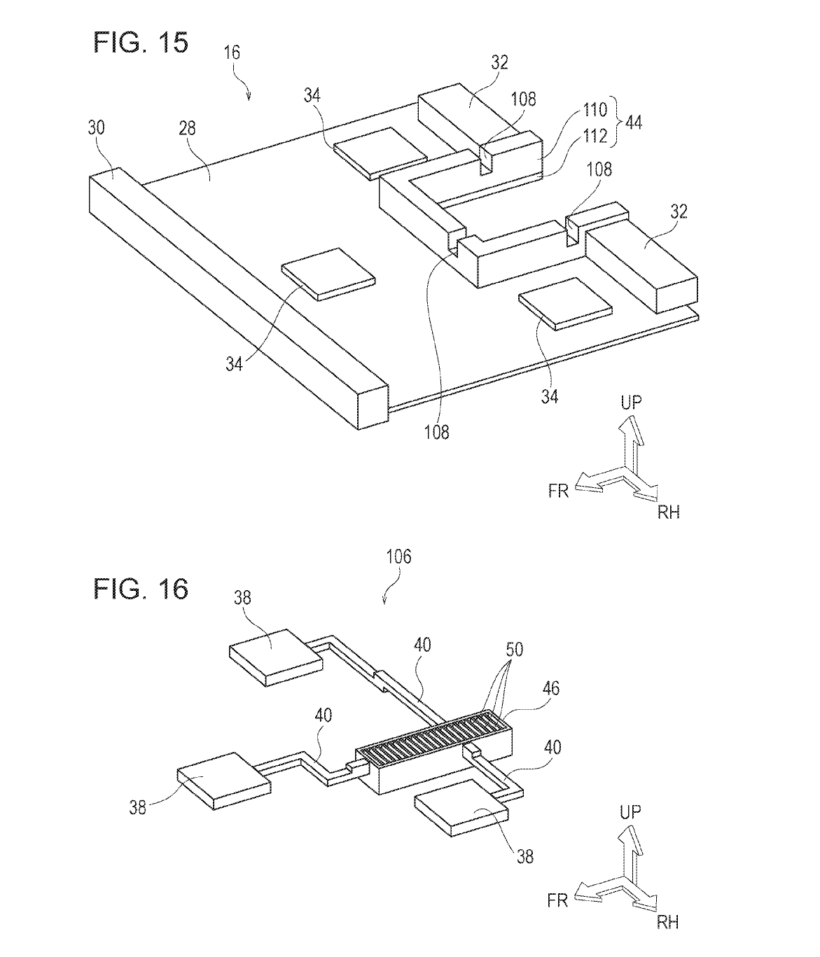

That is, in the board unit 16 according to the fourth embodiment, the duct formation portion 44 and the radiating portion 46 are formed as separate component elements (see FIGS. 15 and 16). The duct formation portion 44 has a first duct formation member 110 and a second duct formation member 112. The first duct formation member 110 and the second duct formation member 112 are fixed to the board 28 from both sides of the board 28 in the board-thickness direction thereof.

As depicted in FIG. 16, the radiating portion 46 and the heat receiving plates 38 are connected via the heat pipes 40. The heat receiving plates 38, the heat pipes 40, and the radiating portion 46 are formed integrally and form a cooling member 106.

In the first duct formation member 110, cut portions 108 are formed in positions corresponding to the heat pipes 40, and longitudinal central parts of the heat pipes 40 are inserted into these cut portions 108. The radiating portion 46 is mounted inside the duct formation portion 44 and forms the radiator 42 with the duct formation portion 44.

Moreover, in an electronic device according to the fourth embodiment, a plurality of types of cooling members 106 are used in accordance with the positions in which the plurality of board units 16 are placed. In the plurality of types of cooling members 106, the position in which the radiating portion 46 is disposed with respect to the duct formation portion 44 in the width direction of the board 28 in one type of cooling member 106 is different from the position in which the radiating portion 46 is disposed with respect to the duct formation portion 44 in the width direction of the board 28 in the other type of cooling member 106. An example in which the position in which the radiating portion 46 is disposed with respect to the duct formation portion 44 in the width direction of the board 28 in one type of cooling member is different from the position in which the radiating portion 46 is disposed with respect to the duct formation portion 44 in the width direction of the board 28 in the other type of cooling member is depicted in FIG. 11 of the third embodiment, for example.

According to the fourth embodiment, the plurality of types of cooling members 106 in which the position in which the radiating portion 46 is disposed with respect to the duct formation portion 44 in one type of cooling member 106 is different from the position in which the radiating portion 46 is disposed with respect to the duct formation portion 44 in the other type of cooling member 106 are used. Therefore, the plurality of types of cooling members 106 only have to be prepared to dispose the radiating portions 46 of the radiators 42 adjacent to each other in the axial direction of the air duct 52 such that the radiating portions 46 are displaced, and, as for the duct formation portions 44, it is possible to use the duct formation portions 44 having the same shape in the plurality of board units 16. As a result, the size of a member whose shape is changed is smaller than the size in a case where, for example, the overall shape of the radiator 42 is changed and a plurality of types of radiators 42 are prepared, which makes it possible to achieve cost reduction.

In the fourth embodiment, a configuration other than those described above is similar to the configurations of the above-described first and second embodiments. In the fourth embodiment, the configuration similar to the configurations of the above-described first and second embodiments produces the operation and effect similar to those of the above-described first and second embodiments.

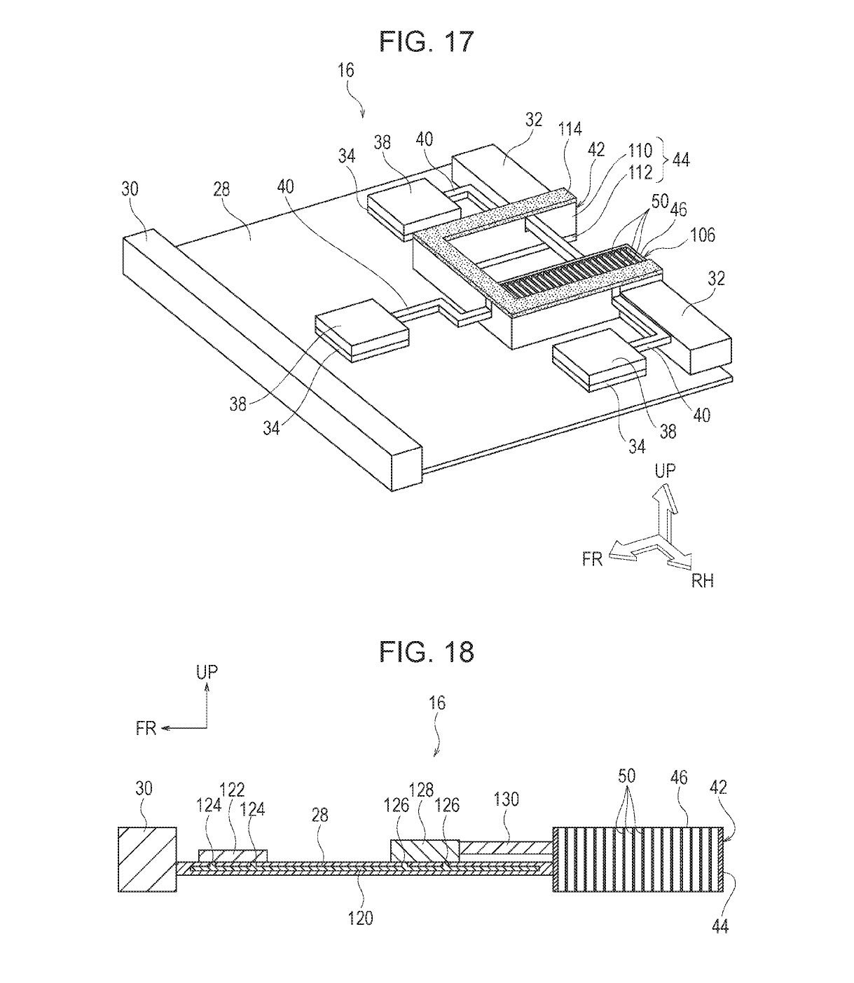

Incidentally, as depicted in FIG. 17, in the fourth embodiment, on a top face of each duct formation portion 44, a gasket 114 formed in the shape of a letter U lying on the side thereof (a letter C) similar to the shape of the duct formation portion 44 in a plan view may be provided.

Since such a configuration makes it possible to fill the space between the adjacent duct formation portions 44 with the gasket 114, it is possible to suppress leakage of the cooling wind from the air duct 52. As a result, it is possible to further reduce the pressure loss of the cooling wind flowing through the air duct 52.

Moreover, in the above-described fourth embodiment, in the plurality of types of cooling members 106, the position in which the radiating portion 46 is disposed with respect to the duct formation portion 44 in the width direction of the board 28 in one type of cooling member 106 is different from the position in which the radiating portion 46 is disposed with respect to the duct formation portion 44 in the width direction of the board 28 in the other type of cooling member 106, but the position in which the radiating portion 46 is disposed with respect to the duct formation portion 44 in the front-back direction of the board 28 in one type of cooling member 106 may be different from the position in which the radiating portion 46 is disposed with respect to the duct formation portion 44 in the front-back direction of the board 28 in the other type of cooling member 106. The front-back direction of the board 28 in this case is an example of the “direction orthogonal to the axial direction of the air duct”.

Furthermore, in the fourth embodiment, as for the configuration similar to the configurations of the above-described first and second embodiments, a modified example similar to those of the above-described first and second embodiment may be adopted.

### Fifth Embodiment

Next, a fifth embodiment of the technique of the present disclosure will be described.

In the fifth embodiment depicted in FIG. 18, the structure of the board unit 16 is changed from that of the above-described first embodiment as follows.

That is, in the fifth embodiment, a heat transfer layer 120 is provided inside the board 28. As the heat transfer layer 120, for example, a thick copper layer which is thicker than a conductive pattern formed in the board 28 is used.

An end of the heat transfer layer 120 is connected, via thermal vias 124, to a heat generation device 122 installed on the board 28. Moreover, the other end of the heat transfer layer 120 is thermally connected to the radiator 42 via thermal vias 126, a heat transfer block 128, and a heat pipe 130. The heat pipe 130 is formed integrally with the heat transfer block 128 and the radiator 42. The heat transfer block 128 is fixed to the board 28 with a thermally conductive adhesive, for example.

According to the fifth embodiment, the heat of the heat generation device 122 is transferred to the heat transfer layer 120 via the thermal vias 124. Moreover, the heat transferred to the heat transfer layer 120 is transferred to the radiator 42 via the thermal vias 126, the heat transfer block 128, and the heat pipe 130. Therefore, it is possible to effectively cool the heat generation device 122 provided in a position away from the radiator 42. This makes it possible to increase the capability of cooling the heat generation device 122.

Incidentally, the heat transfer structure with the heat transfer layer 120 in the fifth embodiment may be applied to the above-described second to fourth embodiments in addition to the first embodiment.

### Sixth Embodiment

Next, a sixth embodiment of the technique of the present disclosure will be described.

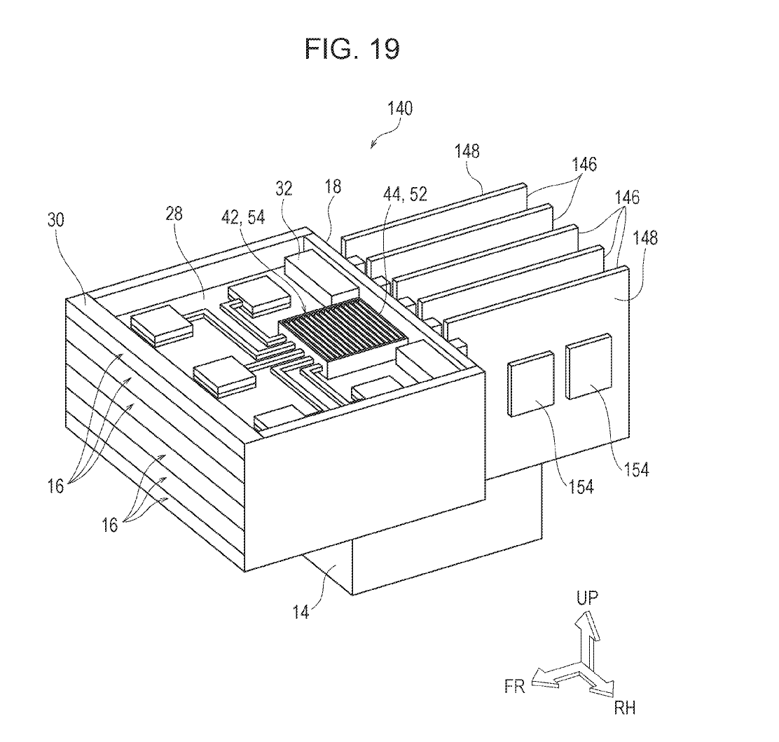

An electronic device 140 according to the sixth embodiment depicted in FIG. 19 has a structure obtained by changing the structure of the electronic device 10 according to the above-described first embodiment as follows.

That is, the electronic device 140 according to the sixth embodiment has a mid-plane structure, and a plurality of board units 146 are provided behind the back wiring board 18.

The plurality of board units 16 disposed in front of the back wiring board 18 are depicted as an example of a “plurality of first board units” and the plurality of board units 146 disposed behind the back wiring board 18 are depicted as an example of a “plurality of second board units”. The plurality of board units 16 disposed in front of the back wiring board 18 and the plurality of board units 146 disposed behind the back wiring board 18 are electrically connected via the back wiring board 18.

Moreover, the plurality of board units 146 disposed behind the back wiring board 18 each have a board 148 and a plurality of heat generation parts 154 installed on the board 148. Each heat generation part 154 is an electronic part which generates heat, such as a central processing unit (CPU).

The plurality of board units 16 disposed in front of the back wiring board 18 are transversely installed, but the plurality of board units 146 disposed behind the back wiring board 18 are longitudinally installed. That is, the boards 148 provided in the plurality of board units 146 disposed behind the back wiring board 18 are disposed in such a way that the board-thickness direction of the board 148 corresponds to a width direction of the electronic device 140. Moreover, the plurality of board units 146 disposed behind the back wiring board 18 are arranged in the width direction of the electronic device 140 which is a direction orthogonal to a direction in which the plurality of board units 16 disposed in front of the back wiring board 18 are arranged.

The fan 14 is disposed below the plurality of board units 16 disposed in front of the back wiring board 18 and the plurality of board units 146 disposed behind the back wiring board 18. The cooling wind sent from the fan 14 is supplied to the inside of the air duct 52 and between the plurality of second board units 146.

According to the sixth embodiment, it is possible to supply the cooling wind by the common fan 14 to the inside of the air duct 52 and between the plurality of second board units 146. This makes it possible to reduce the number of fans as compared to a case where separate fans are used and thereby achieve cost reduction.

Incidentally, the structure with the plurality of board units 146 disposed behind the back wiring board 18 in the sixth embodiment may be applied to the above-described second to fifth embodiments in addition to the first embodiment.

While the first to sixth embodiments of the technique of the present disclosure have been described, the technique of the present disclosure is not limited to those described above. It goes without saying that the embodiments may be carried out by being modified in various ways within the scope of the spirit of the present disclosure.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a plurality of board units, each configured to include a board and a heat generation part installed on the board, the plurality of board units configured to be arranged in an axial direction perpendicular to the board; and
a radiating structure configured to thermally connect with the heat generation part, and include a plurality of duct formation portions provided in the plurality of board units, the plurality of duct formation portions being arranged in the axial direction perpendicular to the board so that an air duct extending in an axial direction perpendicular to each board is formed.

2. The electronic device according to claim 1,
wherein the radiating structure further includes a radiating portion thermally connected with the heat generation part, the radiating structure being provided inside the air duct.

3. The electronic device according to claim 2,
wherein the radiating portion is provided in each of the plurality of duct formation portions, and thermally connected with the heat generation part, in each of the plurality of board units.

4. The electronic device according to claim 2,
wherein the duct formation portion passes through the board in a board-thickness direction of the board, and
wherein the radiating portion includes a plurality of radiating fins formed in the axial direction in which the duct formation portion passes through the board.

5. The electronic device according to claim 2,
wherein the heat generation part is connected with the radiating portion by a heat transfer member.

6. The electronic device according to claim 5,
wherein the heat transfer member includes a heat pipe.

7. The electronic device according to claim 2,
wherein each of the plurality of board units further includes a radiator having the duct formation portion and the radiating portion, and
wherein the radiating portions of radiators adjacent to each other in the axial direction of the air duct, are disposed so as to be displaced in a direction orthogonal to the axial direction of the air duct.

8. The electronic device according to claim 7,
wherein the radiating portions are disposed in a staircase pattern.

9. The electronic device according to claim 2,
wherein the duct formation portion and the radiating portion are formed integrally.

10. The electronic device according to claim 7,
wherein the duct formation portion includes a fixed portion fixed to the board, and a mounted portion mounted on the fixed portion and formed integrally with the radiating portion.

11. The electronic device according to claim 10,
wherein the electronic device includes a plurality of cooling members each having the mounted portion and the radiating portion, in accordance with positions in which the plurality of board units are placed, and
wherein a position in which the radiating portion is formed with respect to the mounted portion in the direction orthogonal to the axial direction of the air duct in one of the cooling members is different from a position in which the radiating portion is formed with respect to the mounted portion in the direction orthogonal to the axial direction of the air duct in the other of the cooling members.

12. The electronic device according to claim 10,
wherein each of the plurality of board units includes
a first heat transfer member configured to connect the heat generation part and the fixed portion, and
a second heat transfer member configured to connect the mounted portion and the radiating portion, and
the first heat transfer member and the second heat transfer member are thermally connected via the fixed portion and the mounted portion.

13. The electronic device according to claim 12,
wherein the second heat transfer member is provided inside the duct formation portion.

14. The electronic device according to claim 7,
wherein the radiating portion is formed separately from the duct formation portion.

15. The electronic device according to claim 14,
wherein the radiating portion is connected with the heat generation part via a heat transfer member,
wherein the electronic device includes a plurality of the cooling members each having the radiating portion and the heat transfer member, in accordance with positions in which the plurality of board units are placed, and
wherein the plurality of the cooling members in which a position in which the radiating portion is disposed with respect to the duct formation portion in the direction orthogonal to the axial direction of the air duct in one of the cooling members is different from a position in which the radiating portion is disposed with respect to the duct formation portion in the direction orthogonal to the axial direction of the air duct in the other of the cooling members.

16. The electronic device according to claim 2,
wherein each of the plurality of board units has a radiator including the duct formation portion and the radiating portion, and
wherein the board has a heat transfer layer connected with a heat generation device installed on the board via a thermal via and thermally connected with the radiator.

17. The electronic device according to claim 1,
wherein the board has an opening in which the duct formation portion is provided.

18. The electronic device according to claim 1, further comprising:
a filler panel unit configured to be arranged, along with the plurality of board units, in the direction perpendicular to the board,
wherein each of the plurality of board units includes a first duct formation portion,
wherein the filler panel unit includes a second duct formation portion, and
wherein the first duct formation portion and the second duct formation portion form the air duct by being arranged in the direction perpendicular to the board.

19. The electronic device according to claim 1, further comprising:
a housing;
a fan connected to the air duct;
an exhaust duct configured to pass air to an upper part of the air duct in an upper part of the housing; and
an inlet duct configured to pass air from a lower part of the air duct in a lower part of the housing,
wherein the plurality of board units are housed in the housing and arranged in a vertical direction of the housing.

20. The electronic device according to claim 1, further comprising:
a plurality of second board units arranged in a direction orthogonal to a direction in which the plurality of board units are arranged; and
a fan configured to supply a cooling wind to an inside of the air duct and between the plurality of second board units.
